(19) United States
(12) Patent Application Publication
(10) Pub. No.: US 2026/0239850 A1
(43) Pub. Date: Aug. 13, 2026

(54) DISPLAY PANEL AND DISPLAY APPARATUS

(71) Applicant: BOE Technology Group Co., Ltd., Beijing (CN)

(72) Inventors: Zhenzhen SHAN, Beijing (CN); Tuo SUN, Beijing (CN); Lujiang HUANGFU, Beijing (CN); Libin LIU, Beijing (CN); Xing YAO, Beijing (CN)

(21) Appl. No.: 19/475,046

(22) PCT Filed: May 24, 2024
(86) PCT No.: PCT/CN2024/095294

§ 371 Date: Oct. 13, 2025

(30) Foreign Application Priority Data
May 29, 2023 (CN) 202310621228.1

(51) Int. Cl. H10K 59/35; H10K 59/122; H10K 59/131

(52) U.S. Cl. CPC H10K 59/353; H10K 59/122; H10K 59/131

(57) ABSTRACT

A display panel and a display apparatus are provided. The display panel includes a base substrate (300); a plurality of pixels (100) on the base substrate (300) and arranged in an array in a first direction and a second direction, each pixel (100) including a plurality of sub-pixels sequentially arranged in a third direction, the third direction intersecting with the first direction and the second direction, and each of the plurality of sub-pixels including a first electrode (301), a luminescent layer (302) and a second electrode (303) sequentially stacked along a direction away from the base substrate (300); a planarization layer (330) arranged on a side of the first electrode (301) close to the base substrate (300); and a conductive layer (320) arranged on a side of the planarization layer (330) close to the base substrate (300), and including a plurality of conductive units (400) arranged in a periodic array in the first direction and the second direction, and each of the plurality of conductive units (400) includes a plurality of conductive sub-units arranged along the first direction, every two adjacent conductive sub-units in a same conductive unit (400) are axisymmetrically arranged, and each sub-pixel corresponds to one conductive sub-unit.

### CROSS-REFERENCE TO RELATED APPLICATIONS

The present application claims the priority of the Chinese Patent Application No. 202310621228.1 filed on May 29, 2023, the content of which is incorporated herein by reference in its entirety.

### TECHNICAL FIELD

The present disclosure relates to the field of display technology, and in particular to a display panel and a display apparatus.

### BACKGROUND

An OLED (organic light-emitting diode) display apparatus may be classified into passive matrix OLED (PMOLED) and active matrix OLED (AMOLED) according to a driving manner. The AMOLED display apparatus has a higher luminescent efficiency and may be used as a large-size display apparatus with a high resolution. While pursuing the high resolution, the problem of poor display of the AMOLED display apparatus is solved in a targeted manner, and this is an important approach to improve the product quality.

### SUMMARY OF THE INVENTION

An object of the embodiments of the present disclosure is to provide a display panel and a display apparatus, to solve the problem of poor display.

In a first aspect, the embodiment of the present disclosure provides a display panel, including: a base substrate; a plurality of pixels on the base substrate, and the plurality of pixels are arranged in an array in a first direction and a second direction, each of the plurality of pixels includes a plurality of sub-pixels sequentially arranged in a third direction, the third direction intersects with the first direction and the second direction, and each of the plurality of sub-pixels includes: a first electrode, a luminescent layer and a second electrode sequentially stacked along a direction away from the base substrate;
a planarization layer arranged on a side of the first electrode close to the base substrate; and a conductive layer arranged on a side of the planarization layer close to the base substrate, including: a plurality of conductive units arranged in a periodic array in the first direction and the second direction, and each of the plurality of conductive units includes: a plurality of conductive sub-units arranged along the first direction, every two adjacent conductive sub-units in the same conductive unit are symmetrically distributed with respect to an axis, and each sub-pixel corresponds to one conductive sub-unit.

In some embodiments, the plurality of sub-pixels includes: a first sub-pixel, a second sub-pixel, and a third sub-pixel, and the plurality of conductive sub-units includes: a first conductive sub-unit corresponding to the first sub-pixel, a second conductive sub-unit corresponding to the second sub-pixel, and a third conductive sub-unit corresponding to the third sub-pixel; and the display panel further includes: a pixel defining layer arranged on a side of the planarization layer away from the base substrate, and including: a first pixel opening for defining a light-emitting region of the first sub-pixel, a second pixel opening for defining a light-emitting region of the second sub-pixel, and a third pixel opening for defining a light-emitting region of the third sub-pixel.

In some embodiments, the first direction is a row direction, the second direction is a column direction, the display panel includes columns of conductive units sequentially separated from each other in the pixel row direction, an orthographic projection of a central axis between an (i+1)th column of conductive units and an i-th column of conductive units on the base substrate is a first projection line, and an orthographic projection of the first pixel opening on the base substrate is a first projection region; and the first projection line approaches or passes through a geometric center point of the first projection region.

In some embodiments, an orthographic projection of a symmetry axis between the first conductive sub-unit and the second conductive sub-unit on the base substrate is a second projection line; and an orthographic projection of the second pixel opening on the base substrate is a second projection region; and the second projection line approaches or passes through a geometric center point of the second projection region.

In some embodiments, an orthographic projection of a symmetry axis between the second conductive sub-unit and the third conductive sub-unit on the base substrate is a third projection line, and an orthographic projection of the third pixel opening on the base substrate is a third projection region; and the third projection line approaches or passes through a geometric center point of the third projection region.

In some embodiments, the first sub-pixel is a blue sub-pixel, the second sub-pixel is a red sub-pixel, and the third sub-pixel is a green sub-pixel, or the second sub-pixel is a green sub-pixel and the third sub-pixel is a red sub-pixel.

In some embodiments, the display panel further includes: a pixel driving circuit layer arranged on a side of the conductive layer close to the base substrate and including a plurality of pixel driving circuits arranged in an array in the first direction and the second direction, and each of the plurality of conductive sub-units includes: a power line extending in the second direction; a flat portion connected to the power line; and a connection portion separated from the flat portion, and the first electrode of each sub-pixel is connected to a corresponding pixel driving circuit through a corresponding connection portion.

In some embodiments, the flat portion of the second conductive sub-unit is connected to the flat portion of the third conductive sub-unit to form a combined flat portion; and an orthographic projection of the third pixel opening on the base substrate is located in an orthographic projection of the combined flat portion on the base substrate.

In some embodiments, along the first direction, a separation distance between the connection portion in the first conductive sub-unit and the connection portion in the second conductive sub-unit is greater than a separation distance between the connection portion in the second conductive sub-unit and the connection portion in the third conductive sub-unit; and an orthographic projection of a geometric center point of the second pixel opening on the base substrate is located between an orthographic projection of the connection portion in the first conductive sub-unit on the base substrate and an orthographic projection of the connection portion in the second conductive sub-unit on the base substrate.

In some embodiments, a coupling point between the first electrode of the first sub-pixel and the connection portion of the first conductive sub-unit is a first coupling point, a coupling point between the first electrode of the second sub-pixel and the connection portion of the second conductive sub-unit is a second coupling point, and a coupling point between the first electrode of the third sub-pixel and the connection portion of the third conductive sub-unit is a third coupling point; and in the second direction, each of a distance between the first coupling point and the first pixel opening and a distance between the third coupling point and the third pixel opening is greater than a distance between the second coupling point and the second pixel opening.

In some embodiments, each of the plurality of conductive sub-units further includes: a data line extending in the second direction; and for each conductive unit, the data line in the first conductive sub-unit and the data line in the second conductive sub-unit are located between the power line in the first conductive sub-unit and the power line in the second conductive sub-unit.

In some embodiments, an orthographic projection of a geometric center point of the second pixel opening on the base substrate is located between an orthographic projection of the data line in the first conductive sub-unit on the base substrate and an orthographic projection of the data line in the second conductive sub-unit on the base substrate.

In some embodiments, an angle between the third direction and the second direction is in a range from 40 degrees to 50 degrees.

In a second aspect, an embodiment of the present disclosure further provides a display apparatus, including: the display panel provided in the first aspect.

The foregoing description is only an overview of the technical solutions provided by the embodiments of the present disclosure, and in order to more clearly understand the technical means of the embodiments of the present disclosure, the present disclosure may be implemented according to the description, and in order to more clearly understand the foregoing and other objects, features, and advantages of the embodiments of the present disclosure, the detailed description of the embodiments of the present disclosure is given as below.

### BRIEF DESCRIPTION OF THE DRAWINGS

The foregoing and various other advantages and benefits of the present disclosure will become apparent to a person skilled in the art upon reading the following detailed description of the preferred embodiments.

FIG. 1 is a schematic diagram illustrating a pixel layout according to some embodiments of the present disclosure;

FIG. 2 is a schematic diagram illustrating a pixel layout according to a comparative example;

FIG. 3 is a cross-sectional view illustrating a display panel according to some embodiments of the present disclosure;

FIG. 4 shows a layout of a conductive layer in FIG. 3;

FIG. 5 is a schematic diagram of a structure of a conductive sub-unit in FIG. 4; and

FIG. 6 is a schematic diagram illustrating a layout of a plurality of pixel openings in a pixel defining layer in FIG. 3.

### DETAIL DESCRIPTION OF THE EMBODIMENTS

The embodiments of the present disclosure will be described more fully hereinafter with reference to the accompanying drawings. The exemplary embodiments of the present disclosure are shown in the drawings, but it should be understood that the present disclosure may be embodied in different forms and should not be construed as limited to the embodiments set forth herein. Rather, these embodiments are provided so that this disclosure will be thorough and complete, and will fully convey the scope of the present disclosure to a person skilled in the art.

It should be noted that, the term “and/or” used herein is only used to describe the association relationship between the associated objects, indicating that there may be three relationships; for example, A and/or B, which may indicate the following three cases: A exists alone, A and B both exist, and B exists alone. The term “a plurality of” used in this disclosure means two or more.

As used herein, the term “about”, “roughly” or “approximately” includes a stated value as well as an average value within an acceptable range of deviation for a particular value as determined by a person skilled in the art in view of the measurement in question and an error associated with a measurement of a particular quantity (i.e., a limitation of a measurement system).

As used herein, the term “parallel”, “perpendicular”, or “equal” includes the recited case and a case similar to the recited case within an acceptable range of deviation as determined by a person skilled in the art in view of the measurement in question and an error associated with a measurement of a particular quantity (i.e., a limitation of a measurement system). For example, the term “parallel” includes “absolutely parallel” and “approximately parallel”, where an acceptable deviation of “approximately parallel” may be, for example, within 5°. The term “perpendicular” includes “absolutely perpendicular” and “approximately perpendicular”, where an acceptable deviation of “approximately perpendicular” may also be, for example, within 5°. The term “equal” includes “absolutely equal” and “approximately equal”, where an acceptable deviation of approximately equal may be a difference between two equal values being less than or equal to 5% of any one of the two values.

It will be understood that, when a layer or element is referred to as being “on” another layer or substrate, the layer or element may be directly on the layer or substrate, or intervening layers may also be present therebetween.

In a first aspect, embodiments of the present disclosure provide a display panel. The display panel may include: a display region and a non-display region. The display region is a region for displaying a picture on the display panel, and the non-display region is a region other than the display region on the display panel. The non-display region may be located on at least one side (e.g., one or more sides) of the display region. In some embodiments, the non-display region may be disposed around the whole circumference of the display region.

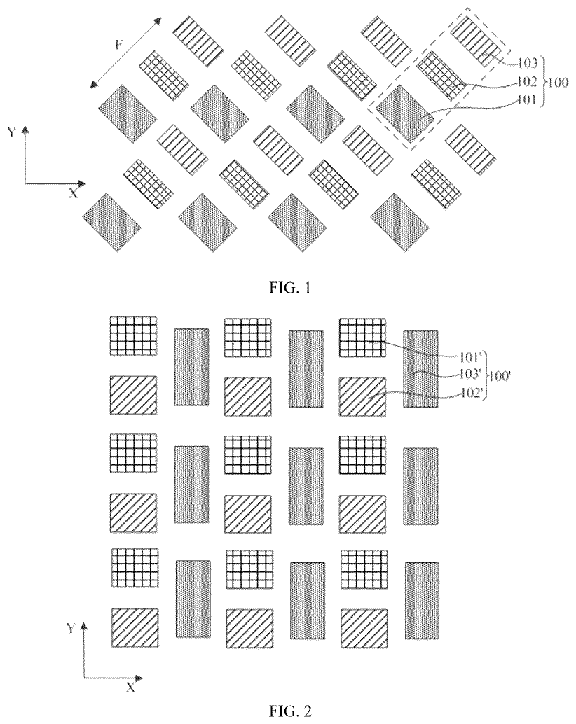

FIG. 1 is a schematic diagram illustrating a pixel layout according to some embodiments of the present disclosure. As shown in FIG. 1, the display region is provided with a plurality of pixels 100 arranged in an array in a first direction and a second direction, and the first direction is indicated by an X-axis in FIG. 1 and the second direction is indicated by a Y-axis in FIG. 1. That is, the plurality of pixels 100 are arranged in M rows and N columns, M, N being an integer greater than or equal to 2. The first direction X is a pixel row direction, and the second direction Y is a pixel column direction. The first direction X and the second direction Y intersect with each other, e.g. are perpendicular to each other.

Each pixel 100 may include a plurality of sub-pixels, each of which may display a single color. For example, a red sub-pixel displays red, a green sub-pixel displays green, and a blue sub-pixel displays blue. The brightness (gray scale) of the sub-pixels of different colors in each pixel 100 may be adjusted, and the display of colors can be realized through the combination and superposition of colors, thereby realizing the full-color display of the display panel.

In some embodiments, the plurality of sub-pixels may include a first sub-pixel 101, a second sub-pixel 102, and a third sub-pixel 103, and the different sub-pixels emit different colors. In some embodiments, the first sub-pixel 101 is a blue sub-pixel, one of the second sub-pixel 102 and the third sub-pixel 103 is a red sub-pixel, and the other is a green sub-pixel. In some embodiments, the second sub-pixel 102 is a red sub-pixel and the third sub-pixel 103 is a green sub-pixel. Alternatively, the second sub-pixel 102 and the third sub-pixel 103 may be a green sub-pixel and a red sub-pixel, respectively.

Each sub-pixel may include a light-emitting device 342 and a pixel driving circuit for driving the light-emitting device 342. In some embodiments, the light-emitting device 342 may be an organic light-emitting diode, a micro organic light-emitting diode (micro OLED), a quantum dot light-emitting diode (QLED), or the like. The red sub-pixel may include a light-emitting device for emitting red light, the green sub-pixel may include a light-emitting device for emitting green light, and the blue sub-pixel may include a light-emitting device for emitting blue light.

The pixel driving circuit may include a plurality of transistors and capacitors and other electronic elements. In some embodiments, the pixel driving circuit may include three transistors and one capacitor, constituting a 3TIC structure (i.e., including one driving transistor, two switching transistors, and one capacitor). The pixel driving circuit may alternatively include more than three transistors and at least one capacitor, such as a 4T1C structure (i.e., including one driving transistor, three switching transistors and one capacitor), a 5TIC structure (i.e., including one driving transistor, four switching transistors and one capacitor), or a 7T1C structure (i.e., including one driving transistor, six switching transistors and one capacitor), or the like. The transistor may be a thin film transistor (TFT), a metal oxide semiconductor transistor (MOS), or other switching devices with the same characteristics.

It will be appreciated that the transistor may include a control electrode, a first electrode and a second electrode. The control electrode is a gate electrode of the transistor, the first electrode is one of a source electrode and a drain electrode of the transistor, and the second electrode is the other of the source electrode and the drain electrode of the transistor. Since the source electrode and the drain electrode of the transistor may be symmetrical in structure, there may be no difference in structure between the source electrode and the drain electrode, and the source electrode of the transistor is referred to as a first electrode or as a second electrode.

The plurality of sub-pixels, such as the first sub-pixel 101, the second sub-pixel 102, and the third sub-pixel 103, are sequentially arranged along the third direction F. As shown in FIG. 1, the first sub-pixel 101, the second sub-pixel 102, and the third sub-pixel 103 in the pixel 100 are sequentially arranged in the third direction F from the bottom left to the top right of FIG. 1. The third direction F intersects with both the first direction X and the second direction Y. In some embodiments, an angle between the third direction F and the second direction Y may be in a range from 40 degrees to 50 degrees. For example, the angle may be one of 40 degrees, 42 degrees, 45 degrees, 48 degrees, 50 degrees, and the like.

FIG. 2 is a schematic diagram illustrating a pixel layout according to a comparative example. As shown in FIG. 2, each pixel 100′ includes a red sub-pixel 101′, a green sub-pixel 102′, and a blue sub-pixel 103′, the red sub-pixel 101′ and the green sub-pixel 102′ are sequentially arranged along the second direction Y, and the blue sub-pixel 103′ is arranged on one side 102′ of the red sub-pixel 101′ and the green sub-pixel. Compared with the pixel arrangement provided by the comparative embodiment, in the embodiment of the present disclosure, a space between two adjacent sub-pixels arranged along the third direction F can be configured as needed, which is beneficial to more fully utilizing the space to arrange the sub-pixels, thereby improving a pixel density (pixels per inch (PPI)), and which is beneficial to solving the problem of reddish or greenish color shift of an upper edge when a horizontal line is displayed, and improving the smoothness of an edge when an oblique line is displayed.

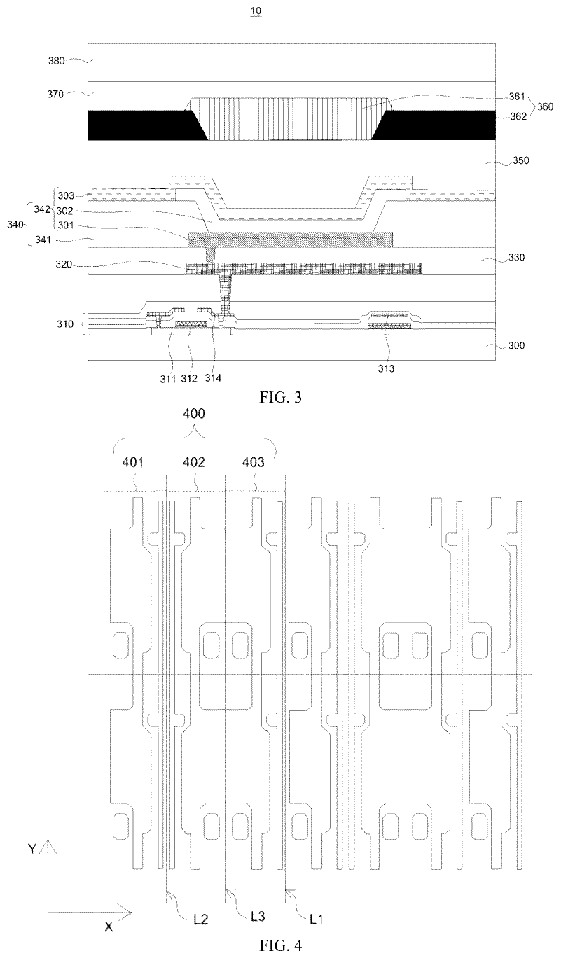

FIG. 3 is a schematic diagram illustrating how to stack a plurality of layers included in a display panel according to some embodiments of the present disclosure. As shown in FIG. 3, the display panel 10 may include a base substrate 300, a pixel driving circuit layer 310, and a light-emitting device layer 340, which are sequentially stacked. The pixel driving circuit layer 310 is configured to form a pixel driving circuit of each sub-pixel, and includes a plurality of pixel driving circuits arranged in an array in the first direction X and the second direction Y. The light-emitting device layer 340 is configured to form a light-emitting device 342 of each sub-pixel. The light-emitting device layer 340 and the pixel driving circuit layer 310 together form a plurality of pixels 100 disposed on the base substrate 300.

In some embodiments, the base substrate 300 may be a rigid substrate. The rigid substrate may include a glass substrate, a PMMA (polymethyl methacrylate) substrate, a silicon substrate, or the like. In this case, the display panel 10 may be a rigid display panel.

In other embodiments, the base substrate 300 may be a flexible substrate. The flexible substrate may include a PET (polyethylene terephthalate) substrate, a PEN (polyethylene naphthalate two formic acid glycol ester) substrate, or a PI (polyimide) substrate, or the like. In this case, the display panel 10 may be a flexible display panel.

It should be noted that the base substrate 300 may have a single-layer structure or a multi-layer structure. In some embodiments, the base substrate 300 may include at least one flexible substrate and at least one buffer layer, which are alternately stacked.

In some embodiments, the pixel driving circuit layer 310 may include: an active layer 311, a first conductive pattern layer 312, a second conductive pattern layer 313, and a third conductive pattern layer 314, which are sequentially stacked. The pixel driving circuit layer 310 may further include an insulating layer separating the functional layers from each other. These layers may form the plurality of pixel driving circuits.

In the embodiment of the present disclosure, the “pattern layer” may be a layer structure including specific patterns formed by forming at least one film layer using the same film forming process and then performing a patterning process on the at least one film layer. Depending on the specific patterns, the patterning process may include a plurality of processes of coating photoresist, exposing, developing or etching, and the specific patterns in the formed layer structure may be continuous or discontinuous, and the specific patterns may be at different heights (or have different thicknesses). The “conductive pattern layer” herein refers to a pattern layer having a conductive property, which is made of a conductive material.

In some embodiments, the active layer 311 may include an active pattern (also referred to as a channel region) of each transistor in the pixel driving circuit. The first conductive pattern layer 312 may also be referred to as a first gate metal layer (Gate1), and may include gate electrodes of the transistors in the pixel driving circuit. The first conductive pattern layer 312 may further include: a first plate of the capacitor in the pixel driving circuit. In some embodiments, a pattern of the gate electrodes of the transistors may be used as the first plate, or the first plate may be additionally disposed in the first conductive pattern layer 312, and the specific structure is set according to actual needs, which is not limited in the embodiments of the present disclosure. The second conductive pattern layer 313, which may also be referred to as a second gate metal layer (Gate2), may include a second plate of the capacitor in the pixel driving circuit. The first plate and the second plate are oppositely arranged, thereby forming the capacitor in the pixel driving circuit. The third conductive pattern layer 314, which may also be referred to as a first metal routing layer (SD1), may include the first electrode and the second electrode, i.e., the source electrode and the drain electrode, of each transistor in the pixel driving circuit.

In some embodiments, the first conductive pattern layer 312, the second conductive pattern layer 313, and the third conductive pattern layer 314 may further include a plurality of signal lines. In some embodiments, the first conductive pattern layer 312 may further include: a reset signal line, a scanning signal line and an enable signal line; the second conductive pattern layer 313 may further include: an initialization signal line, reference may be made to related technologies, and details thereof are not described here.

The light-emitting device layer 340 may include: a pixel defining layer 341, and a plurality of light-emitting devices 342. The pixel defining layer 341 has a plurality of pixel openings, and each pixel opening defines a position of one corresponding light-emitting device 342.

The light-emitting device 342 may include a first electrode 301 (e.g., an anode), a luminescent layer 302, and a second electrode 303 (e.g., a cathode) that are sequentially stacked in a direction away from the base substrate 300. In some embodiments, the light-emitting device layer 340 may further include at least one of a hole injection layer, a hole transport layer, and an electron blocking layer disposed between the first electrode 301 and the luminescent layer 302, and at least one of an electron injection layer, an electron transport layer, and a hole blocking layer disposed between the second electrode 303 and the luminescent layer 302, the specific structure is set according to actual needs, which is not limited in the embodiments of the present disclosure.

In some embodiments, the structure of the first electrode 301 may be a composite structure composed of a transparent conductive oxide film/a metal film/a transparent conductive oxide film, which are sequentially stacked. In some embodiments, the transparent conductive oxide film may be made of any one of ITO (indium tin oxide) or IZO (indium zinc oxide), and the metal film may be made of any one of gold (Au), silver (Ag), nickel (Ni), or platinum (Pt). In other embodiments, the first electrode 301 may alternatively have a single-layer structure made of any one of ITO, IZO, Au, Ag, Ni, and Pt.

Each pixel opening exposes a portion of the first electrode 301 of the corresponding light-emitting device 342, and at least a portion of the luminescent layer 302 is located within the corresponding pixel opening to be electrically connected to the corresponding first electrode 301.

The second electrodes 303 of the light-emitting devices 342 may be electrically connected to each other and have one-piece structure. A material of the second electrode 303 may be any one of aluminum (Al), silver (Ag), and magnesium (Mg), or any one of a magnesium-silver alloy and an aluminum-lithium alloy.

In some embodiments, the display panel 10 may further include: a planarization layer 330 arranged on a side of the first electrode 301 close to the base substrate 300. The pixel defining layer 341 and the plurality of light-emitting devices 342 are located on a side of the planarization layer 330 away from the base substrate 300, and the planarization layer 330 is in contact with the first electrode 301 of the light-emitting device 342.

The display panel 10 may further include: a conductive layer 320 disposed on a side of the planarization layer 330 close to the base substrate 300. The conductive layer 320 is located between the planarization layer 330 and the pixel driving circuit layer 310, and is a metal routing layer under the first electrode 301 and closest to the first electrode 301. In some embodiments, the conductive layer 320 may be in direct contact with the planarization layer 330. In a panel structure with two metal routing layers, the conductive layer 320 may also be referred to as a second metal routing layer (SD2), which includes a plurality of connection portions 503, and the first electrode 301 of each light-emitting device 342 is connected to the corresponding pixel driving circuit through the corresponding connection portion 503. Besides the connection portions 503, the conductive layer 320 may further include other conductive structures, such as a power line, a data line, and the like, which are provided according to actual needs.

It should be noted that in the example provided in the embodiment of the present disclosure, as an example, two metal routing layers are disposed between the second gate metal layer (Gate2) and the first electrode 301. In other examples, more or fewer metal routing layers may be disposed between the second gate metal layer (Gate2) and the first electrode 301. In some embodiments, when three metal routing layers are provided (e.g., including SD1, SD2, and SD3 in that order in a direction away from the base substrate 300), the conductive layer 320 may also be referred to as a third metal routing layer (SD3).

Since the conductive layer 320 has a certain thickness, although the conductive layer 320 and the first electrode 301 are separated from each other by the planarization layer 330, a fluctuation of the pattern of the conductive layer 320 may affect the flatness effect of the planarization layer 330, and thus affect the flatness of the first electrode 301 exposed at the pixel opening. With the pixel arrangement structure shown in FIG. 1 in the embodiment of the present disclosure, if the structure of the conductive layer 320 suitable for the pixel arrangement structure shown in FIG. 2 is still used, it is not favorable to ensure the flatness of the first electrode 301, so that the symmetry of the viewing angle of the sub-pixel is affected, and poor display problems such as color shift are easily caused. Therefore, in order to maximize the flatness of the first electrode 301 on the basis of fully utilizing the space for sub-pixel arrangement to improve the PPI, the embodiment of the present disclosure provides a structure of the conductive layer 320 suitable for the pixel arrangement shown in FIG. 1, and a specific structure of the conductive layer 320 will be described below.

FIG. 4 shows a layout of a conductive layer 320 in FIG. 3. As shown in FIG. 4, the conductive layer 320 may include: a plurality of conductive units 400 arranged in a periodic array in a first direction X and a second direction Y. Each pixel 100 corresponds to one conductive unit 400. For example, the conductive units 400 are arranged periodically in a row direction and periodically in a column direction, each row includes at least N conductive units 400, and each column includes at least M conductive units 400.

Each conductive unit 400 may include: a plurality of conductive sub-units arranged along the first direction X. Every two adjacent conductive sub-units in the same conductive unit 400 are symmetrically arranged with respect to an axis. In some embodiments, an extending direction of a symmetry axis is parallel to the second direction Y. Therefore, when the sub-pixels are arranged along the third direction F, the pattern of the conductive layer 320 covered by the pixel openings of the same sub-pixel is symmetrical as much as possible, so that the flatness of the first electrode 301 of each sub-pixel is improved, the problem of color shift caused by poor flatness of the first electrode 301 is solved, and the display effect is improved. The patterns of the conductive layer 320 covered by the first electrodes 301 of the sub-pixels of the same color may be the same, so that a loading difference among the sub-pixels of the same color is reduced as much as possible, and the brightness uniformity among the sub-pixels of the same color is improved.

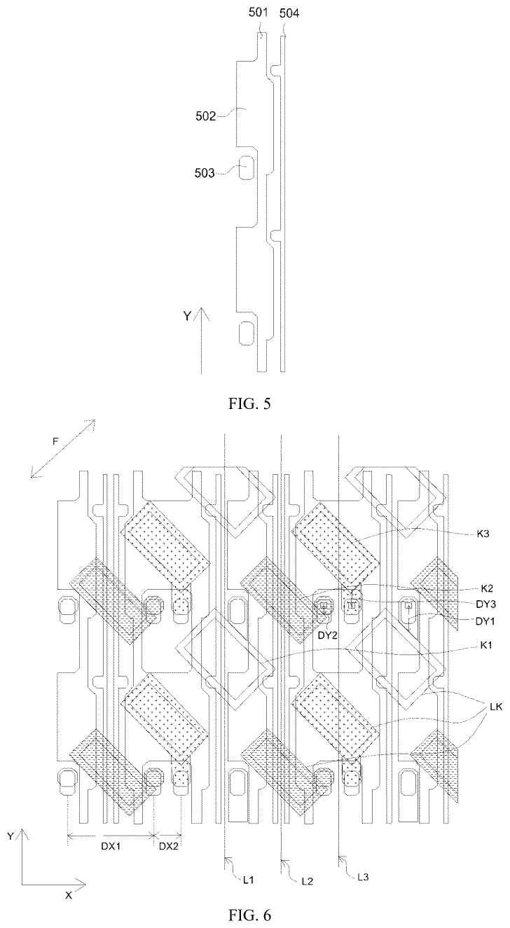

Each sub-pixel corresponds to one conductive sub-unit. As shown in FIG. 5, each conductive sub-unit may include one connection portion 503, and the first electrode 301 in each sub-pixel is connected to the pixel driving circuit through the connection portion 503.

In some embodiments, each pixel 100 may include a first sub-pixel 101, a second sub-pixel 102, and a third sub-pixel 103. Each conductive unit 400 may include: a first conductive sub-unit 401 corresponding to the first sub-pixel 101, a second conductive sub-unit 402 corresponding to the second sub-pixel 102, and a third conductive sub-unit 403 corresponding to the third sub-pixel 103. The first conductive sub-unit 401 and the second conductive sub-unit 402 are symmetrically arranged with respect to an axis, and the second conductive sub-unit 402 and the third conductive sub-unit 403 are symmetrically arranged with respect to an axis. Accordingly, the plurality of pixel openings in the pixel defining layer 341 includes: a first pixel opening K1 for defining a light-emitting region of the first sub-pixel 101, a second pixel opening K2 for defining a light-emitting region of the second sub-pixel 102, and a third pixel opening K3 for defining a light-emitting region of the third sub-pixel 103.

FIG. 6 is a schematic diagram illustrating a layout of a plurality of pixel openings in a pixel defining layer 341 in FIG. 3. In some examples, an area of the first pixel opening K1 is greater than an area of the third pixel opening K3, and the area of the third pixel opening K3 is greater than an area of the second pixel opening K2. That is, an area of an orthographic projection of a lower end of the first pixel opening K1 on the base substrate 300 is larger than an area of an orthographic projection of a lower end of the third pixel opening K3 on the base substrate 300, and the area of the orthographic projection of the lower end of the third pixel opening K3 on the base substrate 300 is larger than an area of an orthographic projection of a lower end of the second pixel opening K2 on the base substrate 300.

In other embodiments, the area of the second pixel opening K2 may be alternatively equal to the area of the third pixel opening K3, or alternatively, the area of the second pixel opening K2 is larger than the area of the third pixel opening K3, which is not limited in the embodiments of the present disclosure.

In some embodiments, a shape of the lower end of the first pixel opening K1, the second pixel opening K2, or the third pixel opening K3 may include, but is not limited to, one or more of a rectangle such as a square, a parallelogram, a prism, a trapezoid, a pentagon, a hexagon, an octagon, an ellipse, and a circle.

A pixel opening includes a pattern type of the rectangle, which means that a shape of the pixel opening is substantially rectangular, either a standard rectangle or a rectangle-like shape with chamfers or rounded corners.

In some embodiments, the first direction X is a pixel row direction, the second direction Y is a pixel column direction, and the display panel 10 includes columns of conductive units sequentially separated from each other in the pixel row direction. An orthographic projection of a central axis between an (i+1)th column of conductive units 400 and an i-th column of conductive units 400 on the base substrate 300 is a first projection line L1, and an orthographic projection of the first pixel opening K1 on the base substrate 300 is a first projection region. Where i is an integer from 1 to S, S is the total number of columns of conductive units 400 included in the conductive layer 320. In order to make the pattern of the conductive layer 320 covered by the first pixel opening K1 symmetrical as much as possible, and therefore, improve the flatness of the first electrode 301 of the second sub-pixel 102, as shown in FIG. 6, in some embodiments, the first projection line L1 may approach (be close to) or pass through a geometric center point of the first projection region. The term “approach or be close to” here means that a separation distance between the first projection line L1 and the geometric center point of the first projection region is small enough to satisfy the acceptable deviation range.

In the same conductive unit 400, an orthographic projection of a symmetry axis between the first conductive sub-unit 401 and the second conductive sub-unit 402 on the base substrate 300 is a second projection line L2. An orthographic projection of the second pixel opening K2 on the base substrate 300 is a second projection region. In order to make the pattern of the conductive layer 320 covered by the second pixel opening K2 symmetrical as much as possible, and therefore, improve the flatness of the first electrode 301 of the second sub-pixel 102, in some embodiments, the second projection line L2 may be close to or pass through a geometric center point of the second projection region, as shown in FIG. 6.

In the same conductive unit 400, an orthographic projection of a symmetry axis between the second conductive sub-unit 402 and the third conductive sub-unit 403 on the base substrate 300 is a third projection line L3. An orthographic projection of the third pixel opening K3 on the base substrate 300 is a third projection region. In order to make the pattern of the conductive layer 320 covered by the third pixel opening K3 symmetrical as much as possible, and therefore, improve the flatness of the first electrode 301 of the third sub-pixel 103, in some embodiments, the third projection line L3 may be close to or pass through a geometric center point of the third projection region.

As an example, the first sub-pixel 101 is a blue sub-pixel, the second sub-pixel 102 is a red sub-pixel, and the third sub-pixel 103 is a green sub-pixel, the first projection line L1 may pass through a geometric center point of the orthographic projection of the first pixel opening K1 on the base substrate 300, the second projection line L2 may pass through a geometric center point of the orthographic projection of the second pixel opening K2 on the base substrate 300, and the third projection line passes through a geometric center point of the orthographic projection of the third pixel opening K3 on the base substrate 300.

In some embodiments, as shown in FIG. 5, each conductive sub-unit may include, in addition to the connection portions 503: a power line 501 and a flat portion 502. The power lines 501 in the same column of conductive sub-units are connected sequentially to form a whole power line 501 extending along the second direction Y, i.e., the column direction.

The flat portion 502 is connected to the power line 501 to provide a relatively flat conductive region. In some embodiments, the flat portion 502 of the second conductive sub-unit 402 is connected to the flat portion 502 of the third conductive sub-unit 403, forming a combined flat portion. The orthographic projection of the third pixel opening K3 on the base substrate 300 is located in an orthographic projection of the combined flat portion on the base substrate 300. That is, a contour of the orthographic projection of the lower end of the third pixel opening K3 on the base substrate 300 is within a contour of the orthographic projection of the combined flat portion on the base substrate 300. In this way, the flatness of the first electrode 301 of the third sub-pixel 103 can be effectively ensured.

In some embodiments, as shown in FIG. 6, the flat portion 502 of the second conductive sub-unit 402 and the flat portion 502 of the third conductive sub-unit 403 may be spliced together along an axial symmetry line of the second conductive sub-unit 402 and the third conductive sub-unit 403, to form a combined flat portion. That is, the axial symmetry line of the second conductive sub-unit 402 and the third conductive sub-unit 403 is a central axis of the combined flat portion in the second direction Y. An area of an orthographic projection of one combined flat portion on the base substrate 300 is twice an area of an orthographic projection of one flat portion 502 on the base substrate 300. When the third sub-pixel 103 is a green sub-pixel, an area of the pixel opening of the green sub-pixel is moderate, and when the first sub-pixel 101, the second sub-pixel 102 and the third sub-pixel 103 are arranged along the third direction F, the pixel opening of the green sub-pixel can be ensured to be covered by the combined flat portion, so that the flatness of the first electrode 301 of the green sub-pixel is ensured.

The connection portion 503 in the conductive sub-unit is separated from, i.e., insulated from the flat portion 502. The first electrode 301 of the sub-pixel is connected to the connection portion 503 of the corresponding conductive sub-unit through a via, and the connection portion 503 may be connected to the corresponding pixel driving circuit through a via, so that the pixel driving circuit drives the light-emitting device 342 included in the sub-pixel.

In some embodiments, the first electrode 301 may include: a body portion and a coupling portion. The body portion and the coupling portion are connected to each other and therefore, have one-piece structure, and the pixel opening exposes at least a portion of the body portion. In some embodiments, an orthographic projection of a portion of the body portion on the base substrate 300 overlaps with an orthographic projection of the pixel opening on the base substrate 300, and an orthographic projection of other portion of the body portion on the base substrate 300 does not overlap with the orthographic projection of the pixel opening on the base substrate 300. In other embodiments, the orthographic projection of the body portion on the base substrate 300 is located within the orthographic projection of the pixel opening on the base substrate 300, and a coupling point of the sub-pixel is located in a region where the coupling portion is located. As shown in FIG. 6, the body portion and the corresponding pixel opening have the same shape, and a contour line LK of the body portion is obtained by expanding the pixel opening corresponding to the body portion outward by one circle, and the contour line LK of the body portion is used as a boundary for the coupling portion and the body portion.

As shown in FIG. 4, in some embodiments, for the same row of conductive units 400, the connection portions 503 in the conductive sub-units may be arranged sequentially along the first direction X. For example, the connection portions 503 in the conductive sub-units in the same row of conductive units 400 may be located on a straight line, and an extending direction of the straight line is parallel to the first direction X.

For convenience of description, the coupling portion of the first sub-pixel 101 is referred to as a first coupling portion, the connection portion 503 in the first conductive sub-unit 401 is referred to as a first connection portion, the coupling portion of the second sub-pixel 102 is referred to as a second coupling portion, the connection portion 503 in the second conductive sub-unit 402 is referred to as a second connection portion, the coupling portion of the third sub-pixel 103 is referred to as a third coupling portion, and the connection portion 503 in the third conductive sub-unit 403 is referred to as a third connection portion. The first coupling portion is connected to the first connection portion through a via, and the second coupling portion is connected to the second connection portion through a via, and the third coupling portion is connected to the third connection portion through a via. A connection point for the via may be referred to as a coupling point for a sub-pixel and a corresponding conductive sub-unit.

As shown in FIG. 6, in some embodiments, for the same conductive unit 400, a separation distance DX1 between the first connection portion and the second connection portion in the first direction X is greater than a separation distance DX2 between the second connection portion and the third connection portion in the first direction X. That is, the connection portions 503 of the conductive sub-units are arranged in the first direction X according to an order of sparse→tight→sparse→tight . . . as shown in FIGS. 4 and 6, which facilitates the layout of the sub-pixels arranged in the third direction F (for example, the sub-pixels may be inserted at sparse positions), and facilitates the coupling of the sub-pixels to the corresponding connection portions 503.

In some embodiments, the orthographic projection of the geometric center point of the second pixel opening K2 on the base substrate 300 is located between the orthographic projection of the first connection portion on the base substrate 300 and the orthographic projection of the second connection portion on the base substrate 300. The second sub-pixel 102 may be a red sub-pixel with a relatively small pixel opening area, so as to facilitate the sub-pixel arrangement.

For convenience of description, a via connection point, which is a coupling point between the first electrode 301 of the first sub-pixel 101 and the first connection portion, is referred to as a first coupling point, a via connection point, which is a coupling point between the first electrode 301 of the second sub-pixel 102 and the second connection portion, is referred to as a second coupling point, and a via connection point, which is a coupling point between the first electrode 301 of the third sub-pixel 103 and the third connection portion, is referred to as a third coupling point.

In the second direction Y, a distance between a geometric center of a coupling point of a sub-pixel in a pixel 100 and the corresponding pixel opening is different from a distance between a geometric center of a coupling point of a different sub-pixel in the same pixel 100 and the corresponding pixel opening. The distance between the coupling point and the pixel opening is a distance from the geometric center of the coupling point to a point on the pixel opening closest to the coupling point along the second direction Y. For convenience of description, a distance between the first coupling point and the first pixel opening K1 along the second direction Y is referred to as a first distance DY1, a distance between the second coupling point and the second pixel opening K2 is referred to as a second distance DY2, and a distance between the third coupling point and the third pixel opening K3 is referred to as a third distance DY3.

In some embodiments, as shown in FIG. 6, when the second sub-pixel 102 is disposed between the first connection portion and the second connection portion, the body portion of the first electrode 301 in the second sub-pixel 102 is relatively closer to the second connection portion. At this time, the first distance DY1 and the third distance DY3 are greater than the second distance DY2.

As shown in FIG. 5, in some embodiments, in addition to the power line 501, the flat portion 502 and the connection portion 503, each conductive sub-unit may further include a data line 504. The data lines 504 in a same column of conductive sub-units are connected sequentially to form a whole data line 504 extending in the second direction Y, i.e., the column direction. That is, one column of conductive sub-units corresponds to one power line 501 extending along the second direction Y and one data line 504 extending along the second direction Y. The data line 504 is separated from the power line 501 and the connection portion 503. Generally, a line width of the data line 504 is smaller than that of the power line 501.

For convenience of description, the data line 504 in the first conductive sub-unit 401 is referred to as a first data line, the data line 504 in the second conductive sub-unit 402 is referred to as a second data line, and the data line 504 in the third conductive sub-unit 403 is referred to as a third data line. The power line 501 in the first conductive sub-unit 401 is referred to as a first power line, the power line 501 in the second conductive sub-unit 402 is referred to as a second power line, and the power line 501 in the third conductive sub-unit 403 is referred to as a third power line.

In the same column of conductive sub-units, the data line 504 may be disposed on a side of the power line 501 away from the connection portion 503. Since the first conductive sub-unit 401 and the second conductive sub-unit 402 are symmetrically arranged with respect to an axis in the first direction X, as shown in FIG. 6, for each conductive unit 400, the first data line and the second data line are located between the first power line and the second power line.

The orthographic projection of the second pixel opening K2 on the base substrate 300 overlaps with an orthographic projection of the first data line on the base substrate 300 and an orthographic projection of the second data line on the base substrate 300. Therefore, in order to make the first data line and the second data line covered by the second pixel opening K2 symmetrical as much as possible, and therefore, improve the flatness of the first electrode 301 of the second sub-pixel 102, the orthographic projection of the geometric center point of the second pixel opening K2 on the base substrate 300 may be located between the orthographic projection of the first data line on the base substrate 300 and the orthographic projection of the second data line on the base substrate 300.

As an example, the first sub-pixel 101 is a blue sub-pixel, the second sub-pixel 102 is a red sub-pixel, and the third sub-pixel 103 is a green sub-pixel, as shown in FIG. 6, the first pixel opening K1 may be located below the first connection portion in FIG. 6, the second pixel opening K2 may be located between the first connection portion and the second connection portion in FIG. 6, and the third pixel opening K3 may be located above the third connection portion in FIG. 6.

At this time, a left corner region of the first pixel opening K1 covers a part of the power line 501 of the previous column of conductive sub-units, a right lower region of the first pixel opening K1 covers a part of the power line 501 and a part of the flat portion 502 of the column of conductive sub-units to which the conductive sub-unit corresponding to the first pixel opening K1 belongs, a middle region of the first pixel opening K1 covers the data line 504 of the previous column of conductive sub-units, and the data line 504 is close to the geometric center point of the second pixel opening K2. A left corner region of the second pixel opening K2 covers a part of the power line 501 of the first conductive sub-unit 401, a right corner region of the second pixel opening K2 covers a part of the power line 501 of the second conductive sub-unit 402, and a middle region of the second pixel opening K2 covers a part of the first data line and a part of the second data line. In this way, the pattern of the conductive layer 320 covered by the first pixel opening K1 and the pattern of the conductive layer 320 covered by the second pixel opening K2 may be symmetrical as much as possible, which is beneficial to improving the flatness of the first electrodes 301 of the first sub-pixel 101 and the second sub-pixel 102. In addition, the entire third pixel opening K3 is covered by the combined flat portion formed by splicing the flat portion 502 of the second conductive sub-unit 402 and the flat portion 502 of the third conductive sub-unit 403, effectively ensuring the flatness of the first electrode 301 of the third sub-pixel 103.

Therefore, the structure of the conductive layer 320 provided by the embodiment of the present disclosure may be applied to the pixel arrangement shown in FIG. 1, which is beneficial to improving the flatness of the first electrode 301 of each sub-pixel, thereby solving the poor display such as color shift caused by the poor flatness of the first electrode 301, and improving the display effect.

In some embodiments, the conductive layers 320 covered by the first electrodes 301 of the first sub-pixels 101 have the same pattern, the conductive layers 320 covered by the first electrodes 301 of the second sub-pixels 102 have the same pattern, and the conductive layers 320 covered by the first electrodes 301 of the third sub-pixels 103 have the same pattern, which is beneficial to reducing the loading difference among the sub-pixels of the same color and improving the brightness uniformity among the sub-pixels of the same color.

As shown in FIG. 3, in some embodiments, the display panel 10 may further include: an encapsulation layer 350 disposed on a side of the light-emitting device layer 340 away from the base substrate 300. In some embodiments, the encapsulation layer 350 may include a first inorganic insulating layer, an organic insulating layer, and a second inorganic insulating layer, which are sequentially stacked. The first inorganic insulating layer and the second inorganic insulating layer may be made of an inorganic material, such as nitride, oxide, oxynitride, nitrate, or carbide, or any combination thereof. The organic insulating layer may be made of acrylic, hexamethyldisiloxane, polyacrylate, polycarbonate, polystyrene or other materials.

As shown in FIG. 3, in some embodiments, the display panel 10 may further include a color filter layer 360. The color filter layer 360 may be disposed on a side of the light-emitting device layer 340 away from the base substrate 300, for example, on a side of the encapsulation layer 350 away from the light-emitting device layer 340. The color filter layer 360 includes a plurality of color filter units 361 and a black matrix 362 disposed between adjacent color filter units 361. Each color filter unit 361 is disposed corresponding to one sub-pixel. For example, the red sub-pixel corresponds to a red filter unit, the green sub-pixel corresponds to a green filter unit, and the blue sub-pixel corresponds to a blue filter unit.

As shown in FIG. 3, in some embodiments, the display panel 10 may further include: a touch layer 380. In this case, the display panel 10 is a touch display panel, and has a touch function and an image display function. The touch layer 380 is configured to provide a touch signal, which may reflect a touch position of a user on the display panel 10.

In some embodiments, the touch layer 380 may be located on a display side of the display panel 10, that is, on a side of the color filter layer 360 away from the base substrate 300. The touch layer 380 may be a separate component from the display panel 10. For example, the display panel 10 and the touch layer 380 are both separately formed and then adhered together by an adhesive such as an optical clear adhesive.

As shown in FIG. 3, in some embodiments, the display panel 10 may further include a buffer layer 370. The buffer layer 370 is disposed on a side of the color filter layer 360 away from the base substrate 300. The touch layer 380 is disposed on the buffer layer 370, and may be in contact with the buffer layer 370. The buffer layer 370 may be made of an organic insulating material or an inorganic insulating material.

In other embodiments, the touch layer 380 may be formed on the encapsulation layer 350 by a photolithography process or other processes. Then, the color filter layer 360 is arranged on a side of the touch layer 380 away from the base substrate 300.

In a second aspect, the embodiment of the present disclosure further provides a display apparatus, which may include: the display panel 10 provided in any one of the embodiments of the present disclosure. For example, the display apparatus may be a mobile phone, a tablet computer, a display, a vehicle-mounted display screen, a digital photo frame, or a wearable display apparatus, such as a VR device, or an AR device, or the like, which is not limited in this embodiment.

In the above description, the technical detail, such as patterning, of the layers of the product is not described in detail. It will be appreciated by a person skilled in the art that layers, regions, and the like of the desired shape may be formed by various technical means. In addition, in order to form the same structure, a person skilled in the art can also design a method which is not exactly the same as the method described above. Although the embodiments are described separately above, this does not mean that the measures in the embodiments cannot be used advantageously in combination.

In addition, a person skilled in the art will understand that: the discussion of any embodiment above is merely exemplary and is not intended to suggest that the scope of the present disclosure is limited to these examples. With the concept of the present disclosure, the technical features from the above embodiments or from different embodiments may alternatively be combined with each other, the steps may be implemented in any order, and there are many other variations of the different aspects of one or more embodiments of the present disclosure as described above, which are not provided in detail for the sake of brevity.

The technical solution provided by the embodiments of the present disclosure at least has the following technical effects or advantages.

According to the display panel and the display apparatus provided by the embodiments of the present disclosure, the plurality of sub-pixels included in each pixel are arranged sequentially along the third direction intersecting with the first direction and the second direction, so that the space is fully utilized for the layout of the sub-pixels, and the density of the pixels in the display panel is improved. On this basis, a conductive layer with a structure suitable for the above layout of the sub-pixels is provided, the conductive layer includes a plurality of conductive units arranged in a periodic array in the first direction and the second direction, each conductive unit includes a plurality of conductive sub-units arranged along the first direction, and every two adjacent conductive sub-units in the same conductive unit are symmetrically arranged with respect to an axis. Therefore, when the sub-pixels are arranged along the third direction, the pattern of the conductive layer covered by the pixel openings of the same sub-pixel is symmetrical as much as possible, so that the flatness of the first electrode of each sub-pixel is improved, the problem of color shift caused by the poor flatness of the first electrode is solved, and the display effect is improved.

While the preferred embodiments of the present disclosure have been described, additional variations and modifications in the embodiments may occur to a person skilled in the art once he learns of the basic inventive concepts. Therefore, the claims are intended to be interpreted as including the preferred embodiments and all changes and modifications that fall within the scope of the present disclosure.

1. A display panel, comprising:
a base substrate;
a plurality of pixels on the base substrate, wherein the plurality of pixels are arranged in an array in a first direction and a second direction, each of the plurality of pixels comprises a plurality of sub-pixels sequentially arranged in a third direction, the third direction intersects with the first direction and the second direction, and each of the plurality of sub-pixels comprises a first electrode, a luminescent layer and a second electrode sequentially stacked along a direction away from the base substrate;
a planarization layer arranged on a side of the first electrode close to the base substrate; and
a conductive layer arranged on a side of the planarization layer close to the base substrate, comprising a plurality of conductive units arranged in a periodic array in the first direction and the second direction, wherein each of the plurality of conductive units comprises a plurality of conductive sub-units arranged along the first direction, every two adjacent conductive sub-units in a same conductive unit are axially symmetric with respect to an axis, and each sub-pixel corresponds to one conductive sub-unit.

2. The display panel of claim 1, wherein the plurality of sub-pixels comprises a first sub-pixel, a second sub-pixel, and a third sub-pixel, and the plurality of conductive sub-units comprises a first conductive sub-unit corresponding to the first sub-pixel, a second conductive sub-unit corresponding to the second sub-pixel, and a third conductive sub-unit corresponding to the third sub-pixel; and
the display panel further comprises a pixel defining layer arranged on a side of the planarization layer away from the base substrate, and comprising a first pixel opening for defining a light-emitting region of the first sub-pixel, a second pixel opening for defining a light-emitting region of the second sub-pixel, and a third pixel opening for defining a light-emitting region of the third sub-pixel.

3. The display panel of claim 2, wherein the first direction is a row direction, the second direction is a column direction, the display panel comprises columns of conductive units distributed at intervals in the row direction, an orthographic projection of a central axis between an (i+1)th column of conductive units and an i-th column of conductive units on the base substrate is a first projection line, and an orthographic projection of the first pixel opening on the base substrate is a first projection region; and
the first projection line approaches or passes through a geometric center point of the first projection region.

4. The display panel of claim 2, wherein an orthographic projection of a symmetry axis between the first conductive sub-unit and the second conductive sub-unit on the base substrate is a second projection line; and an orthographic projection of the second pixel opening on the base substrate is a second projection region; and
the second projection line approaches or passes through a geometric center point of the second projection region.

5. The display panel of claim 2, wherein an orthographic projection of a symmetry axis between the second conductive sub-unit and the third conductive sub-unit on the base substrate is a third projection line, and an orthographic projection of the third pixel opening on the base substrate is a third projection region; and
the third projection line approaches or passes through a geometric center point of the third projection region.

6. The display panel of claim 2, wherein the first sub-pixel is a blue sub-pixel, the second sub-pixel is a red sub-pixel, and the third sub-pixel is a green sub-pixel, or the second sub-pixel is a green sub-pixel and the third sub-pixel is a red sub-pixel.

7. The display panel of claim 2, wherein the display panel further comprises a pixel driving circuit layer arranged on a side of the conductive layer close to the base substrate and comprising a plurality of pixel driving circuits arranged in an array in the first direction and the second direction, and each of the plurality of conductive sub-units comprises:
a power line extending in the second direction;
a flat portion connected to the power line; and
a connection portion separated from the flat portion, wherein the first electrode of each sub-pixel is connected to a corresponding pixel driving circuit through a corresponding connection portion.

8. The display panel of claim 7, wherein the flat portion of the second conductive sub-unit is connected to the flat portion of the third conductive sub-unit to form a combined flat portion; and
an orthographic projection of the third pixel opening on the base substrate is located in an orthographic projection of the combined flat portion on the base substrate.

9. The display panel of claim 7, wherein along the first direction, a separation distance between the connection portion of the first conductive sub-unit and the connection portion of the second conductive sub-unit is greater than a separation distance between the connection portion of the second conductive sub-unit and the connection portion of the third conductive sub-unit; and
an orthographic projection of a geometric center point of the second pixel opening on the base substrate is located between an orthographic projection of the connection portion of the first conductive sub-unit on the base substrate and an orthographic projection of the connection portion of the second conductive sub-unit on the base substrate.

10. The display panel of claim 7, wherein a coupling point between the first electrode of the first sub-pixel and the connection portion of the first conductive sub-unit is a first coupling point, a coupling point between the first electrode of the second sub-pixel and the connection portion of the second conductive sub-unit is a second coupling point, and a coupling point between the first electrode of the third sub-pixel and the connection portion of the third conductive sub-unit is a third coupling point; and
in the second direction, each of a distance between the first coupling point and the first pixel opening and a distance between the third coupling point and the third pixel opening is greater than a distance between the second coupling point and the second pixel opening.

11. The display panel of claim 7, wherein each of the plurality of conductive sub-units further comprises a data line extending in the second direction; and
for each conductive unit, the data line of the first conductive sub-unit and the data line of the second conductive sub-unit are located between the power line of the first conductive sub-unit and the power line of the second conductive sub-unit.

12. The display panel of claim 11, wherein an orthographic projection of a geometric center point of the second pixel opening on the base substrate is located between an orthographic projection of the data line of the first conductive sub-unit on the base substrate and an orthographic projection of the data line of the second conductive sub-unit on the base substrate.

13. The display panel of claim 1, wherein an angle between the third direction and the second direction is in a range from 40 degrees to 50 degrees.

14. A display apparatus, comprising: the display panel of claim 1.

15. The display apparatus of claim 14, wherein the plurality of sub-pixels comprises a first sub-pixel, a second sub-pixel, and a third sub-pixel, and the plurality of conductive sub-units comprises a first conductive sub-unit corresponding to the first sub-pixel, a second conductive sub-unit corresponding to the second sub-pixel, and a third conductive sub-unit corresponding to the third sub-pixel; and
the display panel further comprises a pixel defining layer arranged on a side of the planarization layer away from the base substrate, and comprising a first pixel opening for defining a light-emitting region of the first sub-pixel, a second pixel opening for defining a light-emitting region of the second sub-pixel, and a third pixel opening for defining a light-emitting region of the third sub-pixel.

16. The display apparatus of claim 15, wherein the first direction is a row direction, the second direction is a column direction, the display panel comprises columns of conductive units distributed at intervals in the row direction, an orthographic projection of a central axis between an (i+1)th column of conductive units and an i-th column of conductive units on the base substrate is a first projection line, and an orthographic projection of the first pixel opening on the base substrate is a first projection region; and
the first projection line approaches or passes through a geometric center point of the first projection region.

17. The display apparatus of claim 15, wherein an orthographic projection of a symmetry axis between the first conductive sub-unit and the second conductive sub-unit on the base substrate is a second projection line; and an orthographic projection of the second pixel opening on the base substrate is a second projection region; and
the second projection line approaches or passes through a geometric center point of the second projection region.

18. The display apparatus of claim 15, wherein an orthographic projection of a symmetry axis between the second conductive sub-unit and the third conductive sub-unit on the base substrate is a third projection line, and an orthographic projection of the third pixel opening on the base substrate is a third projection region; and
the third projection line approaches or passes through a geometric center point of the third projection region.

19. The display apparatus of claim 15, wherein the first sub-pixel is a blue sub-pixel, the second sub-pixel is a red sub-pixel, and the third sub-pixel is a green sub-pixel, or the second sub-pixel is a green sub-pixel and the third sub-pixel is a red sub-pixel.

20. The display apparatus of claim 15, wherein the display panel further comprises a pixel driving circuit layer arranged on a side of the conductive layer close to the base substrate and comprising a plurality of pixel driving circuits arranged in an array in the first direction and the second direction, and each of the plurality of conductive sub-units comprises:
a power line extending in the second direction;
a flat portion connected to the power line; and
a connection portion separated from the flat portion, wherein the first electrode of each sub-pixel is connected to a corresponding pixel driving circuit through a corresponding connection portion.
